(19) United States
(12) Patent Application Publication
(10) Pub. No.: US 2026/0113924 A1
(43) Pub. Date: Apr. 23, 2026

(54) SEMICONDUCTOR STRUCTURE AND MANUFACTURING METHOD THEREOF

(71) Applicant: Winbond Electronics Corp., Taichung City (TW)

(72) Inventors: Yu-Ting Chen, Kaohsiung (TW); Shuo-Ting Yu, Tainan City (TW); Hsuan-Tung Chu, Tainan City (TW); Wei-Che Chang, Taichung City (TW)

(73) Assignee: Winbond Electronics Corp., Taichung City (TW)

(21) Appl. No.: 18/976,361

(22) Filed: Dec. 11, 2024

(30) Foreign Application Priority Data
Oct. 22, 2024 (TW) 113140192

(51) Int. Cl. H10B 12/00

(52) U.S. Cl. CPC H10B 12/09; H10B 12/34; H10B 12/50

(57) ABSTRACT

Providing are a semiconductor structure and a manufacturing method thereof. The semiconductor structure includes a substrate, a first isolation structure, a second isolation structure, a word line, a pad layer, a cover layer and a dummy pattern. The substrate has a memory device region and a peripheral region. The first isolation structure is disposed in the substrate in the memory device region to define an active area. The second isolation structure is disposed in the substrate in the peripheral region. The word line is disposed in the substrate in the active area. The pad layer is disposed on the substrate in the memory device region. The cover layer is disposed on the pad layer and extends downward to the top surface of the word line. The dummy pattern is disposed in the second isolation structure.

### CROSS-REFERENCE TO RELATED APPLICATION

This application claims the priority benefit of Taiwan application serial no. 113140192, filed on Oct. 22, 2024. The entirety of the above-mentioned patent application is hereby incorporated by reference herein and made a part of this specification.

### BACKGROUND

### Technical Field

The present invention relates to a semiconductor structure and a manufacturing method thereof.

### Description of Related Art

In the current semiconductor process, the forming method of the shallow trench isolation (STI) structure may include the following steps. First, a trench is formed in the substrate. Then, the spin-on glass (SOG) may be formed in the trench through the spin coating and filled with the trench. That is, the STI structure is mainly constituted by the SOG.

For the STI structure with a large layout area, in the subsequent process, when the etching process is performed to remove the layer on the STI structure, the dishing may be generated at the top surface of the STI structure. As a result, the STI structure cannot have a flat surface, and the process residue may be remained in the dishing in the subsequent processes.

### SUMMARY

The present invention provides a semiconductor structure and a manufacturing method thereof, in which the isolation structure in the peripheral region has a flat top surface without the dishing.

The semiconductor structure of the present invention includes a substrate, a first isolation structure, a second isolation structure, a word line, a pad layer, a cover layer and a dummy pattern. The substrate has a memory device region and a peripheral region. The first isolation structure is disposed in the substrate in the memory device region to define an active area. The second isolation structure is disposed in the substrate in the peripheral region. The word line is disposed in the substrate in the active area. The pad layer is disposed on the substrate in the memory device region. The cover layer is disposed on the pad layer and extends downward to a top surface of the word line. The dummy pattern is disposed in the second isolation structure.

The manufacturing method of the semiconductor structure of the present invention includes the following steps. A substrate having a memory device region and a peripheral region is provided. A first isolation structure is formed in the substrate in the memory device region to define an active area. A second isolation structure is formed in the substrate in the peripheral region. A word line is formed in the substrate in the active area. A pad layer is formed on the substrate in the memory device region. A cover layer is formed on the pad layer, wherein the cover layer extends downward to a top surface of the word line. A dummy pattern is formed in the second isolation structure.

Based on the above, in the semiconductor structure and the manufacturing method thereof of the present invention, since the dummy patterns are formed in the isolation structure in the peripheral region and the material of the dummy patterns is different from the material of the isolation structure, the dishing may be avoided from being generated on the top surface of the isolation structure during the etching process. Therefore, in subsequent processes, the process residues may not be remained on the isolation structure in the peripheral region.

### BRIEF DESCRIPTION OF THE DRAWINGS

FIGS. 1A to 1H are schematic cross-sectional views of the manufacturing process of the semiconductor structure of the embodiment of the present invention.

FIG. 2 is a schematic cross-sectional view along the extending direction of the word line trench in FIG. 1C.

FIG. 3 is a schematic cross-sectional view along the extending direction of the word line trench in FIG. 1D.

### DESCRIPTION OF THE EMBODIMENTS

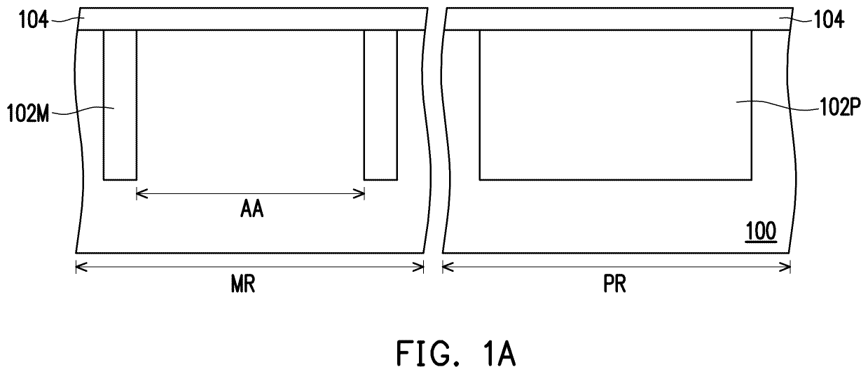

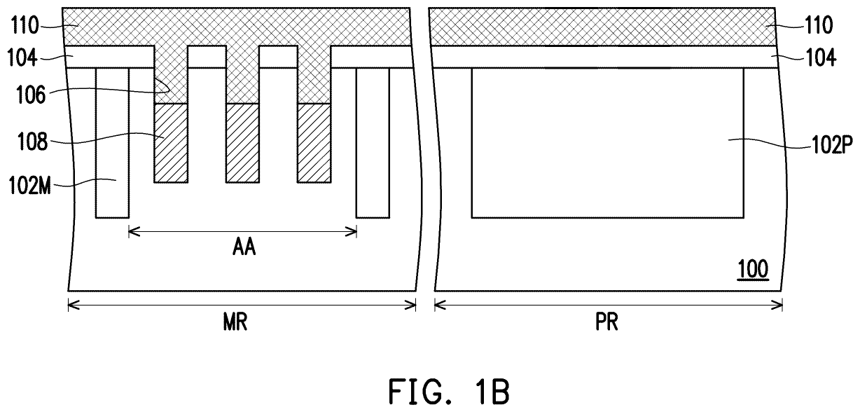

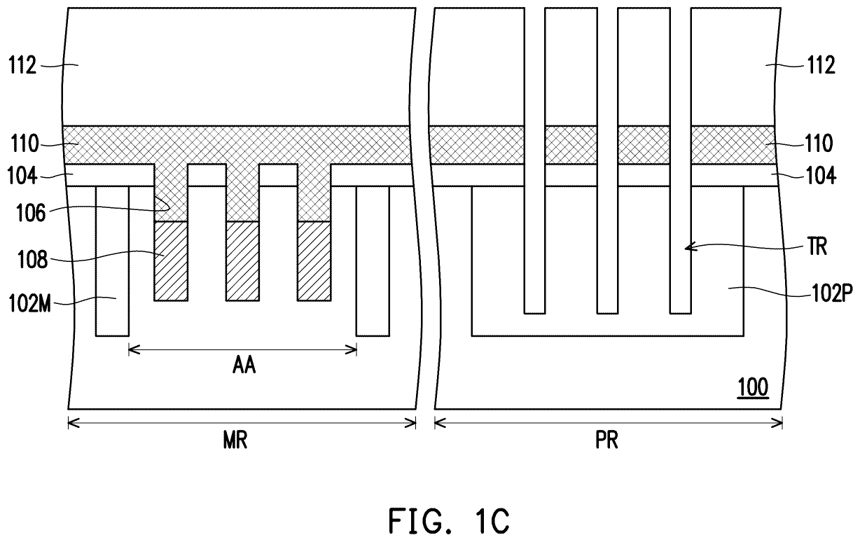

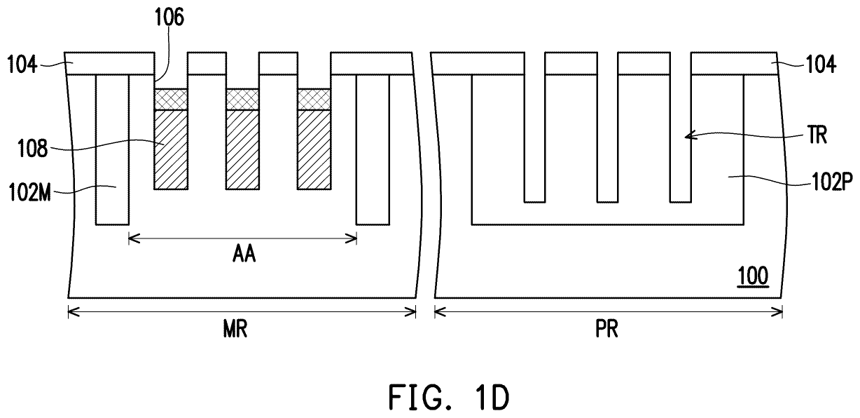

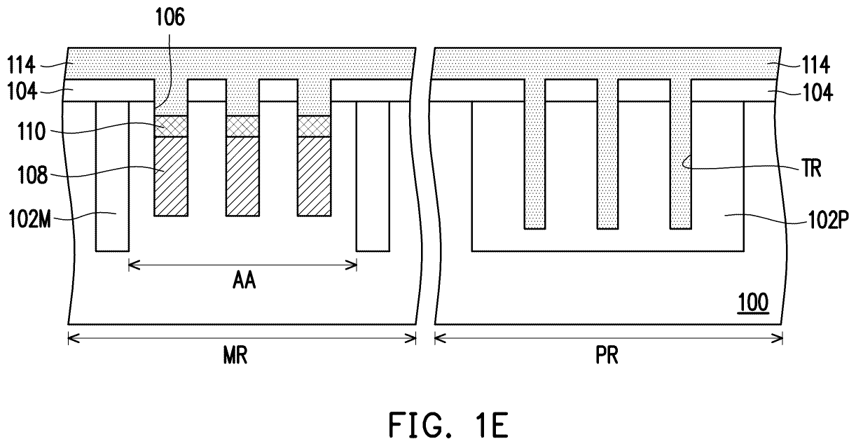

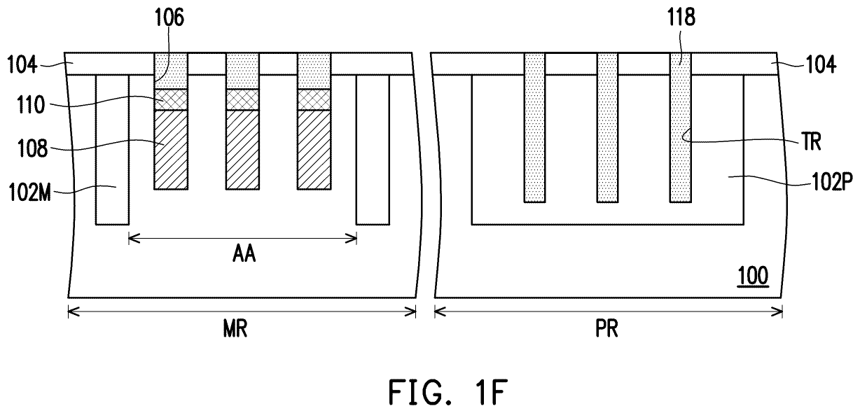

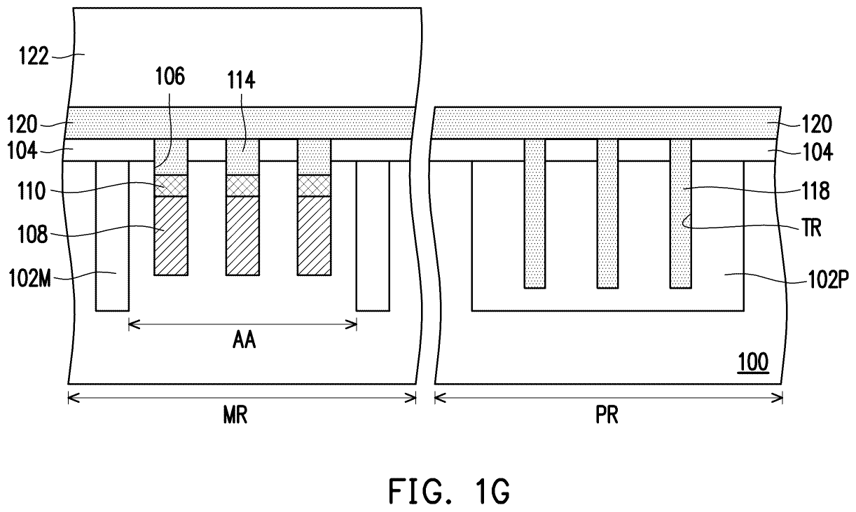

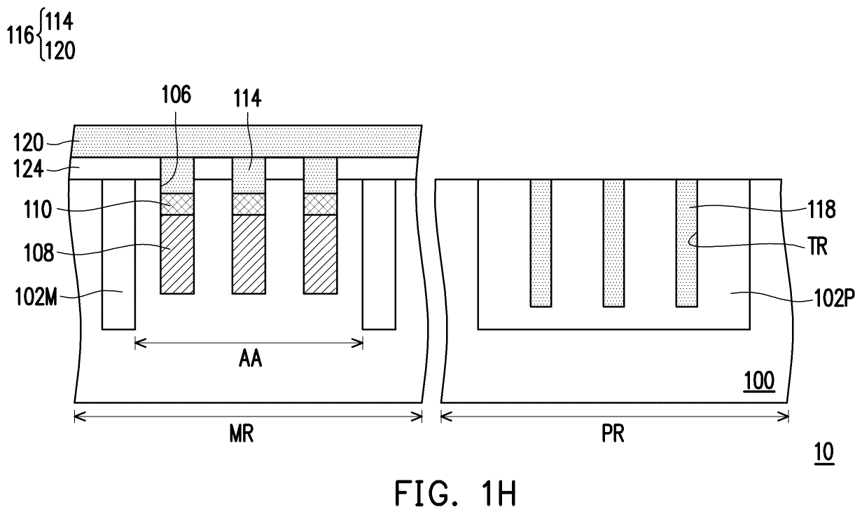

FIGS. 1A to 1H are schematic cross-sectional views of the manufacturing process of the semiconductor structure of the embodiment of the present invention.

Referring to FIG. 1A, a substrate 100 is provided. In the present embodiment, the substrate 100 may be a silicon substrate, but the present invention is not limited thereto. The substrate 100 has a memory device region MR and a peripheral region PR. In the present embodiment, the memory device region MR is a region used to form a memory device having a buried word line, and the peripheral region PR is a region used to form other semiconductor devices.

Next, an isolation structure 102M is formed in the substrate 100 in the memory device region MR to define an active area AA, and an isolation structure 102P is formed in the substrate 100 in the peripheral region PR. The isolation structure 102P has a larger size than the isolation structure 102M. The active area AA is a region used to form the memory device in the memory device region MR. The material of the isolation structure 102M and the material of the isolation structure 102P are, for example, silicon oxide. In the present embodiment, the isolation structure 102M and the isolation structure 102P are, for example, STI structures. The forming method of the isolation structure 102M and the isolation structure 102P is well known to those skilled in the art and will not be described further here.

Afterwards, a pad material layer 104 is formed on the substrate 100. The material of the pad material layer 104 is, for example, silicon oxide. The pad material layer 104 is used to prevent the substrate 100 from being damaged in the subsequent processes.

Referring to FIG. 1B, an anisotropic etching process is performed on the pad material layer 104 and the substrate 100 in the active area AA to form word line trenches 106 in the substrate 100 in the active area AA. The word line trench 106 is used to accommodate the buried word line of the memory device. In the present embodiment, the bottom surface of the word line trench 106 is higher than the bottom surface of the isolation structure 102M. In FIG. 1B, the number of word line trenches 106 is only exemplary and is not limited by the present invention.

Then, a conductive layer 108 is formed in the word line trenches 106. In the present embodiment, the conductive layer 108 is formed at the bottom of the word line trenches 106 and does not fill the word line trenches 106. The material of the conductive layer 108 is, for example, metal. For example, the conductive layer 108 may be a tungsten layer. The forming method of the conductive layer 108 may include the following steps. First, a conductive material layer is formed on the substrate 100, and the conductive material layer fills the word line trenches 106. Afterwards, an etching-back process is performed on the conductive material layer to remove the conductive material layer on the top surface of the substrate 100 and a part of the conductive material layer in the word line trenches 106.

Afterwards, a conductive layer 110 is formed on the pad material layer 104. The conductive layer 110 fills the word line trenches 106. The material of the conductive layer 110 is polysilicon, for example.

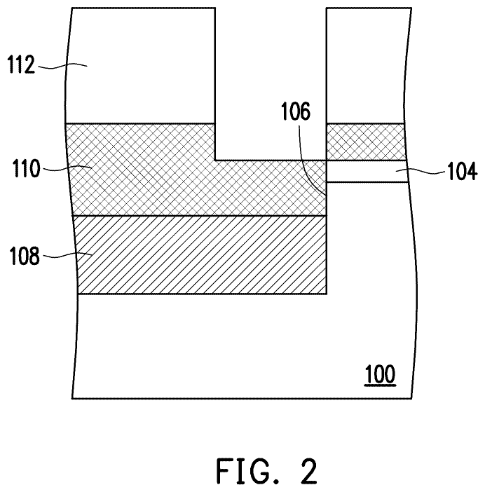

Referring to FIG. 1C, a patterned mask layer 112 is formed on the conductive layer 110. The material of the patterned mask layer 112 is, for example, photoresist material. The patterned mask layer 112 exposes a region corresponding to a position of a dummy pattern subsequently formed in the isolation structure 102P, and exposes a part of the conductive layer 110 in the word line trenches 106. In the present embodiment, the patterned mask layer 112 exposes the end of the conductive layer 110 in the word line trench 106. As shown in FIG. 2, in the extending direction of the word line trench 106 (the direction perpendicular to the drawing of FIG. 1C), the patterned mask layer 112 exposes a portion of the conductive layer 110 in the word line trench 106 adjacent to the sidewall of the word line trench 106.

After that, using the patterned mask layer 112 as a mask, an etching process is performed to remove a part of the conductive layer 110, a part of the pad material layer 104 and a part of the isolation structure 102P. Specifically, in the memory device region MR, the patterned mask layer 112 is used as the mask, and a part of the exposed conductive layer 110 is removed, so that the thickness of the exposed conductive layer 110 is reduced, as shown in FIG. 2. In addition, in the peripheral region PR, the patterned mask layer 112 is used as the mask, and the exposed conductive layer 110 and the pad material layer 104 and the part of the isolation structure 102P thereunder are removed, so that pattern trenches TR are formed in the isolation structure 102P. In FIG. 1C, the shape, the number and the depth of the pattern trenches TR are only exemplary and are not limited by the present invention.

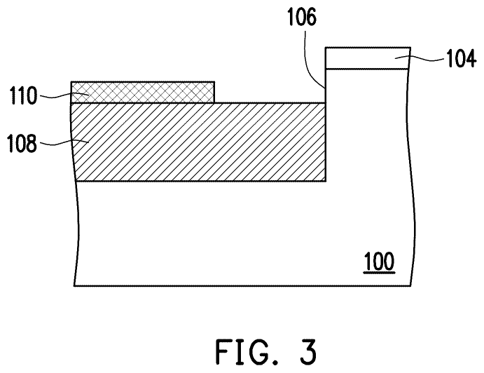

Referring to FIG. 1D, the patterned mask layer 112 is removed. Afterwards, an etching-back process is performed to remove the conductive layer 110 on the pad material layer 104 and a part of the conductive layer 110 in the word line trenches 106 to expose a part of the top surface of the conductive layer 108. That is, in the word line trench 106, the conductive layer 110 is located on a part of the top surface of the conductive layer 108. As shown in FIG. 3, in the extending direction of the word line trench 106 (the direction perpendicular to the drawing in FIG. 1D), the conductive layer 110 is located on the conductive layer 108, and the portion of the conductive layer 108 adjacent to the sidewall of the word line trench 106 is exposed.

In the present embodiment, the conductive layer 108 and the conductive layer 110 in the word line trench 106 constitute a buried word line, and the exposed portion of the conductive layer 108 may be used as a contact region where the buried word line to be electrically connected to the external device.

Referring to FIG. 1E, a cover material layer 114 is formed on the pad material layer 104. The cover material layer 114 fills the word line trenches 106 and the pattern trenches TR. The material of the cover material layer 114 is silicon nitride, for example.

Referring to FIG. 1F, the cover material layer 114 on the pad material layer 104 is removed, leaving the cover material layer 114 located in the word line trenches 106 and the pattern trenches TR. The cover material layer 114 in pattern trenches TR constitutes dummy patterns 118. That is, the dummy patterns 118 are formed in the isolation structure 102P, and the material of the dummy patterns 118 is different from the material of the isolation structure 102P and the material of the material of the pad material layer 104.

In the present embodiment, the method for removing the cover material layer 114 on the pad material layer 104 is, for example, performing an etching-back process. Since the dummy patterns 118 are formed in the isolation structure 102P and the material of the dummy patterns 118 is different from the material of the isolation structure 102P and the material of the pad material layer 104, the dishing on the top surface of the pad material layer 104 may be suppressed during the etching-back process. That is, in the present embodiment, after removing the cover material layer 114 on the pad material layer 104, the pad material layer 104 may still have a flat surface without the dishing.

Referring to FIG. 1G, a cover material layer 120 is formed on the pad material layer 104. The material of cover material layer 120 is silicon nitride, for example. Next, a mask layer 122 is formed on the cover material layer 120 in the memory device region MR. The material of mask layer 122 is, for example, photoresist material. The mask layer 122 exposes the cover material layer 120 in the peripheral region PR.

Referring to FIG. 1H, using the mask layer 122 as a mask, an etching-back process is performed to remove the cover material layer 120, the pad material layer 104 and the dummy patterns 118 outside the isolation structure 102P in the peripheral region PR. Then, the mask layer 122 is removed. In this way, a semiconductor structure 10 of the present embodiment is formed.

In the present embodiment, since dummy patterns 118 are formed in isolation structure 102P and the material of the dummy patterns 118 is different from the material of isolation structure 102P and the material of the pad material layer 104, the occurrence of the dishing on the top surface of the isolation structure 102P may be suppressed during the etching-back process. That is, in the present embodiment, after removing the cover material layer 120, the pad material layer 104 and the dummy patterns 118 outside the isolation structure 102P in the peripheral region PR, in the semiconductor structure 10, the isolation structure 102P may have a flat surface, and the top surface of the dummy patterns 118, the top surface of the isolation structure 102P and the top surface of the substrate 100 in peripheral region PR may be coplanar. Therefore, when performing subsequent processes on the semiconductor structure 10, the process residue may not be remained on the isolation structure 102P.

In addition, in the semiconductor structure 10, the cover material layer 120 and the cover material layer 114 remained in the memory device region MR constitute a cover layer 116, and the pad material layer 104 remained in the memory device region MR constitutes a pad layer 124. That is, the cover layer 116 is formed on the pad layer 124 and extends downward to the top surface of the word line constituted by the conductive layer 108 and the conductive layer 110, that is, the cover layer 116 covers the top surface of the conductive layer 110 and the exposed top surface of the conductive layer 108.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
s substrate, having a memory device region and a peripheral region;
a first isolation structure, disposed in the substrate in the memory device region to define an active area;
a second isolation structure, disposed in the substrate in the peripheral region;
a word line, disposed in the substrate in the active area;
a pad layer, disposed on the substrate in the memory device region;
a cover layer, disposed on the pad layer and extending downward to a top surface of the word line; and
a dummy pattern, disposed in the second isolation structure.

2. The semiconductor structure of claim 1, wherein a material of the cover layer and a material of the dummy pattern comprise silicon nitride.

3. The semiconductor structure of claim 1, wherein a material of the first isolation structure and a material of the second isolation structure comprise silicon oxide.

4. The semiconductor structure of claim 1, wherein a material of the pad layer comprises silicon oxide.

5. The semiconductor structure of claim 1, wherein a top surface of the dummy pattern, a top surface of the second isolation structure and a top surface of the substrate in the peripheral region are coplanar.

6. The semiconductor structure of claim 1, wherein the word line comprises a first conductive layer and a second conductive layer disposed on the first conductive layer, and the second conductive layer exposes a part of a top surface of the first conductive layer.

7. The semiconductor structure of claim 6, wherein the cover layer covers a top surface of the second conductive layer and the exposed top surface of the first conductive layer.

8. The semiconductor structure of claim 6, wherein a material of the first conductive layer comprises metal.

9. The semiconductor structure of claim 6, wherein a material of the second conductive layer comprises polysilicon.

10. A manufacturing method of a semiconductor structure, comprising:
providing a substrate having a memory device region and a peripheral region;
forming a first isolation structure in the substrate in the memory device region to define an active area;
forming a second isolation structure in the substrate in the peripheral region;
forming a word line in the substrate in the active area;
forming a pad layer on the substrate in the memory device region;
forming a cover layer on the pad layer, wherein the cover layer extends downward to a top surface of the word line; and
forming a dummy pattern in the second isolation structure.

11. The manufacturing method of claim 10, wherein a forming method of the word line, the pad layer, the cover layer and the dummy pattern comprises:
forming a pad material layer on the substrate after forming the first isolation structure and the second isolation structure;
forming a word line trench in the substrate in the active area;
forming a first conductive layer in the word line trench;
forming a second conductive layer on the pad material layer, wherein the second conductive layer fills the word line trench;
removing a part of the second conductive layer, a part of the pad material layer and a part of the second isolation structure to form a pattern trench in the pad material layer and the second isolation structure in the peripheral region, and remaining a part of the second conductive layer in the word line trench, wherein the remained second conductive layer exposes a part of a top surface of the first conductive layer;
forming a first cover material layer on the pad material layer, wherein the first cover material layer fills the word line trench and the pattern trench;
removing the first cover material layer on the pad material layer;
forming a second cover material layer on the pad material layer; and
removing the second cover material layer and the pad material layer in the peripheral region.

12. The manufacturing method of claim 11, wherein a material of the first cover material layer and a material of the second cover material layer comprise silicon nitride.

13. The manufacturing method of claim 11, wherein a material of the pad material layer comprises silicon oxide.

14. The manufacturing method of claim 11, wherein a method for removing a part of the second conductive layer, a part of the pad material layer and a part of the second isolation structure comprises:
forming a patterned mask layer on the second conductive layer;
performing a first etching process by using the patterned mask layer as a mask to remove a part of the second conductive layer in the word line trench and a part of the second conductive layer, a part of the pad material layer and a part of the second isolation structure in the peripheral region;
removing the patterned mask layer; and
performing a second etching process to remove the second conductive layer on the pad material layer and a part of the second conductive layer in the word line trench, so that a part of the first conductive layer is exposed.

15. The manufacturing method of claim 11, wherein a method for removing the first cover material layer on the pad material layer comprises performing an etching-back process.

16. The manufacturing method of claim 11, wherein a method for removing the second cover material layer and the pad material layer in the peripheral region comprises:
forming a mask layer on the second cover material layer in the memory device region;
performing an etching-back process by using the mask layer as a mask to remove the second cover material layer, the pad material layer and the dummy pattern outside the second isolation structure in the peripheral region; and
removing the mask layer.

17. The manufacturing method of claim 11, wherein a material of the first conductive layer comprises metal.

18. The manufacturing method of claim 11, wherein a material of the second conductive layer comprises polysilicon.

19. The manufacturing method of claim 10, wherein a material of the first isolation structure and a material of the second isolation structure comprise silicon oxide.

20. The manufacturing method of claim 10, wherein a top surface of the dummy pattern, a top surface of the second isolation structure and a top surface of the substrate in the peripheral region are coplanar.
